(19) United States
(12) Patent Application Publication
(10) Pub. No.: US 2013/0118258 A1
(43) Pub. Date: May 16, 2013

(54) INERTIAL SENSOR AND METHOD OF MANUFACTURING THE SME

(71) Applicant: SAMSUNG ELECTRO-MECHANICS CO., LTD., Gyunggi-do (KR)

(72) Inventors: Jong Woon Kim, Gyunggi-do (KR); Yun Sung Kang, Gyunggi-do (KR)

(73) Assignee: SAMSUNG ELECTRONICS CO., LTD., Gyunggi-do (KR)

(21) Appl. No.: 13/650,532

(22) Filed: Oct. 12, 2012

(30) Foreign Application Priority Data
Nov. 10, 2011 (KR) 10-2011-0117156

(51) Int. Cl. G01P 15/00; H01L 41/22

(52) U.S. Cl. 73/514.35; 29/25.35

(57) ABSTRACT

Disclosed herein are an inertial sensor and a method of manufacturing the same. The inertial sensor includes: a flexible part; a mass body movably supported by the flexible part and including a metal; a post supporting the flexible part; piezoelectric elements driving the mass body or sensing displacement of the mass body; and a package enclosing the flexible part, the mass body, and the post, wherein the metal has a melting point lower than the Curie temperature of the piezoelectric elements and higher than that of a solder forming connection parts for a surface mounting technology (SMT) provided on the package.

### CROSS REFERENCE TO RELATED ED APPLICATION

This application claims the benefit of Korean Patent Application No. 10-2011-0117156, filed on Nov. 10, 2011, entitled “Inertial Sensor and Method of Manufacturing The Same”, which is hereby incorporated by reference in its entirety into this application.

### BACKGROUND OF THE INVENTION

1. Technical Field

The present invention relates to an inertial sensor and a method of manufacturing the same.

2. Description of the Related Art

Recently, an inertial sensor has been used as various applications, for example, military such as an artificial satellite, a missile, an unmanned aircraft, or the like, vehicles such as an air bag, electronic stability control (ESC), a black box for a vehicle, or the like, hand shaking prevention of a camcoder, motion sensing of a mobile phone or a game machine, navigation, or the like,

The inertial sensor generally adopts a configuration in which a mass body is adhered to an elastic substrate such as membrane, or the like, in order to measure acceleration and angular velocity. Through the configuration, the inertial sensor may calculate the acceleration by measuring inertial force applied to the mass body and may calculate the angular velocity by measuring Coriolis force applied to the mass body.

In detail, a scheme of measuring the acceleration and the angular velocity using the inertial sensor is as follows. First, the acceleration may be implemented by Newton's law of motion “F=ma”, where “F” represents inertial force applied to the mass body, “m” represents a mass of the mass body, and “a” is acceleration to be measured. Among others, the acceleration a may be obtained by sensing the inertial force F applied to the mass body and dividing the sensed inertial force F by the mass m of the mass body that is a predetermined value. Further, the angular velocity may be obtained by Coriolis force “F=2mΩQ×v”, where “F” represents the Coriolis force applied to the mass body, “m” represents the mass of the mass body, “Ω” represents the angular velocity to be measured, and “v” represents the motion velocity of the mass body. Among others, since the motion velocity V of the mass body and the mass m of the mass body are values known in advance, the angular velocity Ω may be obtained by detecting the Coriolis force (F) applied to the mass body.

In order to measure the acceleration and the angular velocity in the above-mentioned scheme, the inertial sensor according to the prior art adopts a configuration in which a mass body is adhered to a flexible membrane such as a diaphragm, or the like, as disclosed in Japanese Registration Patent No. 4216525(Japanese Patent Publication No. 2003-329702)

However, in the inertial sensor according to the prior art, since the mass body is formed of silicon, the mass body has relatively low density, such that a signal to noise ratio is low. Therefore, sensitivity of the inertial sensor is deteriorated. In order to solve this problem, the density of the mass body should be increased. However, a method of manufacturing an inertial sensor by a precise process while increasing density of a mass body is not present until now.

### SUMMARY OF THE INVENTION

The present invention has been made in an effort to provided a method of manufacturing an inertial sensor capable of improving sensitivity by forming a mass body using a metal having high density and preventing a piezoelectric element from being damaged and preventing a mass body from being melted by having a melting point of the mass body lower than the Curie temperature of the piezoelectric element and higher than that of a solder forming connection parts for a surface mounting technology (SMT).

According to a preferred embodiment of the present invention, there is provided an inertial sensor including: a flexible part; a mass body movably supported by the flexible part and including a metal; a post supporting the flexible part; piezoelectric elements driving the mass body or sensing displacement of the mass body; and a package enclosing the flexible part, the mass body, and the post, wherein the metal has a melting point lower than the Curie temperature of the piezoelectric elements and higher than that of a solder forming connection parts for a surface mounting technology (SMT) provided on the package.

The piezoelectric element may be formed of lead zirconate titanate (PZT), barium titanate (BaTiO₃), lead titanate (PbTiO₃), lithium niobate (LiNbO₃), or quartz (SiO₂).

The solder forming the connection part for an SMT may have a ratio of tin (Sn) to lead (Pb) of 63%:37%.

The metal may be a solder having a melting point higher than that of the solder forming the connection part for an SMT.

The metal may be a solder formed of tin (Sn) and lead (Pb), and the solder may have a melting point higher than a eutectic temperature of tin (Sn) and lead (Pb).

The mass body may include an interface layer formed therein.

According to another preferred embodiment of the present invention, there is provided an inertial sensor including: a flexible part; a mass body movably supported by the flexible part and including a metal; a post supporting the flexible part; piezoelectric elements driving the mass body or sensing displacement of the mass body; and connection parts for an SMT provided on the package enclosing the flexible part, the mass body, and the post and formed using a solder, wherein the metal has a melting point lower than the Curie temperature of the piezoelectric elements and higher than that of the solder forming the connection parts for an SMT.

The inertial sensor may further include a main board electrically connected to the connection parts for an SMT.

According to still another preferred embodiment of the present invention, there is provided a method of manufacturing an inertial sensor, the method including: (A) forming piezoelectric elements on one surface of a base substrate; (B) forming a first concave part in the other surface of the base substrate; (C) forming a mass body in the first concave part by filling a filling material including a metal therein; (D) forming a depressed second concave part in the other surface of the base substrate at an outer side of the mass body and forming a flexible part on an upper portion of the second concave part in the base substrate; and (E) enclosing the base substrate with a package and forming connection parts for an SMT on the package, the connection parts for an SMT being formed using a solder, wherein the metal has a melting point lower than the Curie temperature of the piezoelectric elements and higher than that of the solder forming the connection parts for an SMT.

The piezoelectric element may be formed of lead zirconate titanate (PZT), barium titanate (BaTiO₃), lead titanate (PbTiO₃), lithium niobate (LiNbO₃), or quartz (SiO₂).

The solder forming the connection part for an SMT may have a ratio of tin (Sn) to lead (Pb) of 63%:37%.

The metal may be a solder having a melting point higher than that of the solder forming the connection part for an SMT.

The metal may be a solder formed of tin (Sn) and lead (Pb), and the solder may have a melting point higher than a eutectic temperature of tin (Sn) and lead (Pb).

The method may further include, before step (C), forming an interface layer in the first concave part.

According to still another preferred embodiment of the present invention, there is provided a method of manufacturing an inertial sensor, the method including: (A) forming piezoelectric elements on one surface of a base substrate; (B) forming a penetration part penetrating through the base substrate; (C) forming a mass body in the penetration part by filling a filling material including a metal therein; (D) forming a flexible part patterned so as to penetrate through the base substrate at an outer side of the mass body; and (E) enclosing the base substrate with a package and forming connection parts for an SMT on the package, the connection parts for an SMT being formed using a solder, wherein the metal has a melting point lower than the Curie temperature of the piezoelectric elements and higher than that of the solder forming the connection parts for an SMT.

The piezoelectric element may be formed of lead zirconate titanate (PZT), barium titanate (BaTiO₃), lead titanate (PbTiO₃), lithium niobate (LiNbO₃), or quartz (SiO₂).

The solder forming the connection part for an SMT may have a ratio of tin (Sn) to lead (Pb) of 63%:37%.

The metal may be a solder having a melting point higher than that of the solder forming the connection part for an SMT.

The metal may be a solder formed of tin (Sn) and lead (Pb), and the solder may have a melting point higher than a eutectic temperature of tin (Sn) and lead (Pb).

The method may further include, before step (C), forming an interface layer in the penetration part.

### BRIEF DESCRIPTION OF THE DRAWINGS

FIGS. 1A and 1B are cross-sectional views of an inertial sensor according to a first preferred embodiment of the present invention;

FIG. 2 is a cross-sectional view of an inertial sensor according to a second preferred embodiment of the present invention;

FIGS. 3 to 8 are cross-sectional views sequentially showing a method of manufacturing an inertial sensor according to the first preferred embodiment of the present invention;

FIGS. 9 to 14 are cross-sectional views sequentially showing a method of manufacturing an inertial sensor according to the second preferred embodiment of the present invention; and

FIG. 15 is a graph showing a change in a melting point of a solder formed of tin (Sn) and lead (Pb) according to a content of the lead (Pb).

### DESCRIPTION OF THE PREFERRED EMBODIMENTS

Various objects, advantages and features of the invention will become apparent from the following description of embodiments with reference to the accompanying drawings.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe most appropriately the best method he or she knows for carrying out the invention.

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. In the description, the terms “first”, “second”, and so on are used to distinguish one element from another element, and the elements are not defined by the above terms. Further, in describing the present invention, a detailed description of related known functions or configurations will be omitted so as not to obscure the subject of the present invention.

Hereinafter, preferred embodiments of the present invention will be described in detail with reference to the accompanying drawings.

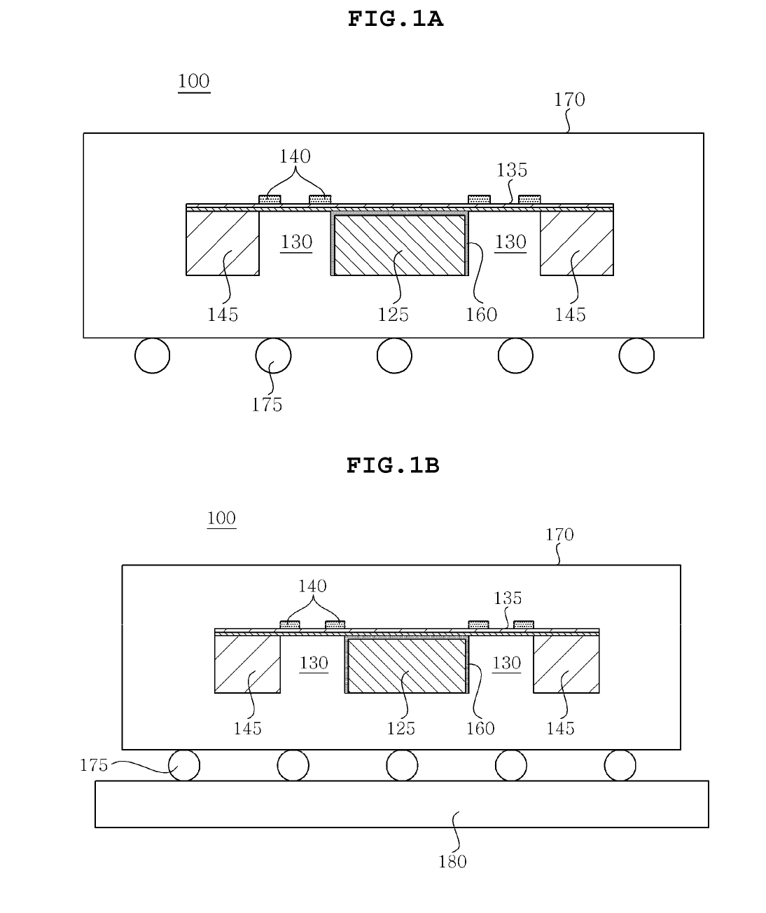

FIGS. 1A and 1B are cross-sectional views of an inertial sensor according to a first preferred embodiment of the present invention.

As shown in FIGS. 1A and 1B, the inertial sensor 100 according to the present embodiment is configured to include a flexible part 135, a mass body 125 movably supported by the flexible part 135 and including a metal, a post 145 supporting the flexible part 135, piezoelectric elements 140 driving the mass body 125 or sensing displacement of the mass body 125, and a package 170 enclosing the flexible part 135, the mass body 125, and the post 145, wherein the metal has a melting point lower than the Curie temperature of the piezoelectric elements 140 and higher than that of a solder forming connection parts 175 for a surface mounting technology (SMT) provided on the package 170.

The flexible part 135 is formed in a plate shape to thereby have elasticity so that the mass body 125 may be displaced. That is, the flexible part 135 is supported by the post 145 to thereby be elastically deformed corresponding to the displacement of the mass body 125 when the mass body 125 is displaced. In addition, the flexible part 135 may be a part relatively thinned by forming a depressed second concave part 130 in, for example, a silicon-on-insulator (SOI) substrate.

The mass body 125, which is movably supported by the flexible part 135, may be displaced by inertial force or Coriolis force and be driven by the piezoelectric elements 140. In addition, the mass body 125 may include the metal. More specifically, the mass body 125 may be formed by melting the metal. As described above, the mass body 125 is formed of the metal, such that density of the mass body 125 is increased, thereby making it possible to improve sensitivity of the inertial sensor 100, and Brownian noise is decreased, thereby making it possible to increase a signal to noise ratio. Here, as the metal forming the mass body 125, a solder having an excellent bonding property and a cheap cost may be used.

Additionally, an interface layer 160 may be formed on the mass body 125. Here, the interface layer 160, which is formed of a gold plating layer, or the like, serves to improve wettability during a manufacturing process. The interface layer will be described in detail with respect to a manufacturing process.

The post 145, which supports the flexible part 135, secures a space in which the mass body 125 may be displaced. That is, the post 145 supports the flexible part 145 to thereby become references of the displacement of the mass body 125 when the mass body 125 is displaced. In addition, the post 145 may be a part remaining at an outer side of the second concave part 130 after the second concave part 130 is formed in, for example, the SOI substrate.

The piezoelectric elements 140 serve to drive the mass body 125 or sense the displacement of the mass body 125. More specifically, the mass body 125 may be driven using an inverse piezoelectric effect that the piezoelectric elements 140 are expanded and contracted when voltage is applied to the piezoelectric elements 140. The displacement of the mass body 125 may be sensed using a piezoelectric effect that a potential difference is generated when stress is applied to the piezoelectric elements 140. As described above, a wiring layer (not shown) connected to the piezoelectric elements 140 may be formed in order to drive the mass body 125 or sense the displacement of the mass body 125 through the piezoelectric element 140. In addition, the piezoelectric element 140 may be formed of lead zirconate titanate (PZT), barium titanate (BaTiO₃), lead titanate (PbTiO₃), lithium niobate (LiNbO₃), quartz (SiO₂) or the like.

Meanwhile, since the flexible part 135 is elastically deformed corresponding to the displacement of the mass body 125, it is preferable that the piezoelectric elements 140 are disposed on the flexible part 135. However, all of the piezoelectric elements 140 are not necessarily disposed on the flexible part 135 but some of the piezoelectric elements 140 may be disposed on the mass body 125 or the post 145.

The package 170 encloses the flexible part 135, the mass body 125, and the post 145 in order to protect the flexible part 135, the mass body 125, the post 145, the piezoelectric elements 140, and the like, from external impact. Here, the package 170 may be formed by performing a molding process in a mold machine and then performing a post mold cure (PMC) process in an oven.

The connection parts 159 for an SMT, which serve to electrically connect wirings in the package 170 and a main board 180 such as a printed circuit board (PCB), or the like, to each other, are provided on an outer side of the package 170. Here, the connection part 175 for an SMT may be formed using a solder and be generally defined as a solder ball.

Meanwhile, the metal forming the mass body 125 has a melting point lower than the Curie temperature of the piezoelectric element 140 and higher than that of the solder forming the connection part 175 for an SMT. That is, the Curie temperature of the piezoelectric element 140 is higher than the melting point of the metal forming the mass body 125, and the melting point of the metal forming the mass body 125 is higher than the melting point of the solder forming the connection part 175 for an SMT. This is to prevent the piezoelectric elements 140 from being damaged when the mass body 125 is formed or prevent the mass body 125 from being melted when the connection part 175 for an SMT is formed since the inertial sensor 100 is formed in a sequence of the piezoelectric elements 140→the mass body 125→the connection part 175 for an SMT.

For example, when the piezoelectric element 140 is formed of PZT, since the Curie temperature of the piezoelectric element 140 is 350 to 400° C., the metal forming the mass body 125 needs to have a melting point lower than 350° C. However, this is only an example. When the piezoelectric element 140 is formed of a material other than the PZT, the metal forming the mass body 125 needs to have a melting point lower than the Curie temperature of the material other than the PZT.

In addition, the metal forming the mass body 125 needs to have a melting point higher than that of the solder forming the connection part 175 for an SMT. Here, as the metal forming the mass body 125, a solder having an excellent bonding property and a cheap cost may be used. In this case, even though both of the mass body 125 and the connection part 175 for an SMT are formed using the solder, since the melting point of the solder may be controlled according to a component ratio thereof, the melting point of the solder forming the mass body 125 may become higher than that of the solder forming the connection part 175 for an SMT. FIG. 15 is a graph showing a change in a melting point of a solder formed of tin (Sn) and lead (Pb) according to a content of the lead (Pb). Referring to FIG. 15, the solder has a eutectic temperature (approximately 183° C.), which is the lowest melting point, in the case in which a ratio of tin (Sn) to lead (Pb) is 63%:37% and has a melting point higher than the eutectic temperature in the case in which a ratio of tin (Sn) to lead (Pb) is a ratio other than the above-mentioned ratio. Therefore, the solder forming the connection part 175 for an SMT may have a ratio of tin (Sn) to lead (Pb) of 63%:37% so that it has the relatively lowest melting point. In addition, the solder forming the mass body 125 may have a melting point higher than the eutectic temperature of the tin (Sn) and the lead (Pb) by allowing the ratio of tin (Sn) to lead (Pb) not to become 63%:37%. However, this is only an example and the present invention is not necessarily limited thereto. That is, the mass body 125 may be formed of any metal material having a melting point higher than that of the solder forming the connection part 175 for an SMT.

Meanwhile, as shown in FIG. 1B, the inertial sensor 100 according to the present embodiment may further include the main board 180 electrically connected to the connection parts 175 for an SMT. That is, the wirings in the package 170 and the main board 180 are electrically connected to each other using the connection parts 175 for an SMT. As a result, the package 170 is mounted on the main board 180 using the SMT.

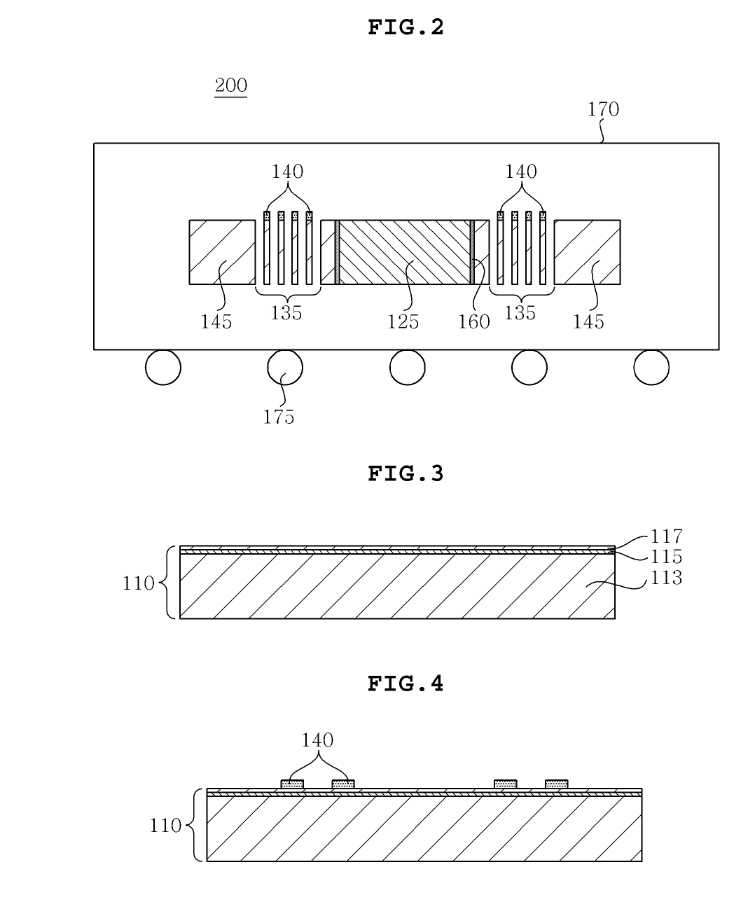

FIG. 2 is a cross-sectional view of an inertial sensor according to a second preferred embodiment of the present invention.

As shown in FIG. 2, the inertial sensor 200 according to the present embodiment is different in a structure of a mass body 125, a flexible part 135, and the like, from the inertial sensor 100 according to the first preferred embodiment of the present invention described above. Therefore, in the present embodiment, portions overlapped with those of the first preferred embodiment will be omitted and the mass body 125, the flexible part 135, and the like, will be mainly described.

The flexible part 135 according to the present embodiment is formed in a cantilever shape to thereby have elasticity so that the mass body 125 may be displaced. That is, the flexible part 135 is supported by the post 135 to thereby be elastically deformed corresponding to the displacement of the mass body 125 when the mass body 125 is displaced. In addition, the flexible part 135 may be formed by performing the patterning so as to penetrate through, for example, an SOI substrate.

In addition, the mass body 125, which is movably supported by the flexible part 135, may be displaced by inertial force or Coriolis force and be driven by the piezoelectric elements 140. Here, the mass body 125 may include the metal. More specifically, the mass body 125 may be formed by melting the metal. Additionally, an interface layer 160 such as a gold plating layer, or the like, may be formed on the mass body 125.

In addition, the post 145 supports the flexible part 135 so that the mass body 125 may be displaced. That is, the post 145 supports the flexible part 145 to thereby become references of the displacement of the mass body 125 when the mass body 125 is displaced. Here, the post 145 may be a part remaining at an outer side of the flexible part 135 after the flexible part 135 is formed by performing the patterning so as to penetrate through the SOI substrate.

Also in the inertial sensor 200 according to the present embodiment, the mass body 125 is formed of the metal, such that density of the mass body 125 is increased, thereby making it possible to improve sensitivity of the inertial sensor 200, and Brownian noise is decreased, thereby making it possible to increase a signal to noise ratio. In addition, the metal forming the mass body 125 has a melting point lower than the Curie temperature of the piezoelectric element 140 and higher than that of the solder forming the connection part 175 for an SMT. Therefore, even though the inertial sensor 200 is formed in a sequence of the piezoelectric elements 140→the mass body 125→the connection part 175 for an SMT, it is possible to prevent the piezoelectric elements 140 from being damaged when the mass body 125 is formed or prevent the mass body 125 from being melted when the connection part 175 for an SMT is formed.

FIGS. 3 to 8 are cross-sectional views sequentially showing a method of manufacturing an inertial sensor according to the first preferred embodiment of the present invention.

As shown in FIGS. 3 to 8, the method of manufacturing an inertial sensor 100 according to the present embodiment includes (A) forming piezoelectric elements 140 on one surface of a base substrate 110, (B) forming a first concave part 120 in the other surface of the base substrate 110, (C) forming a mass body 125 in the first concave part 120 by filling a filling material including a metal therein, (D) forming a depressed second concave part 130 in the other surface of the base substrate 110 at an outer side of the mass body 125 and forming a flexible part 135 on an upper portion of the second concave part 130 in the base substrate 110, and (E) enclosing the base substrate 110 with a package 170 and forming connection parts 175 for an SMT on the package 170, the connection parts 175 for an SMT being formed using a solder, wherein the metal has a melting point lower than the Curie temperature of the piezoelectric elements 140 and higher than that of the solder forming the connection parts 175 for an SMT.

First, as shown in FIG. 3, the base substrate 110 is prepared. Here, as the base substrate 110, a silicon-on-insulator (SOI) substrate on which a micro electromechanical systems (MEMS) process is easily performed may be used. Here, the SOI substrate is formed by sequentially stacking a first silicon layer 113, a silicon oxide layer 115, and a second silicon layer 117. However, the case in which the SOI substrate is used as the base substrate 110 is only an example. That is, the base substrate 110 is not necessarily limited to being the SOI substrate but may be all substrates known in the art such as a silicon substrate, or the like.

Then, as shown in FIG. 4, the piezoelectric elements 140 are formed on one surface of the base substrate 110. Here, the piezoelectric element 140 may be formed by depositing lead zirconate titanate (PZT), barium titanate (BaTiO₃), lead titanate (PbTiO₃), lithium niobate (LiNbO₃), quartz (SiO₂), or the like. In addition, a wiring layer (not shown) may be formed and connected to the piezoelectric elements 140 in order to drive the mass body 125 or sense the displacement of the mass body 125 through the piezoelectric elements 140.

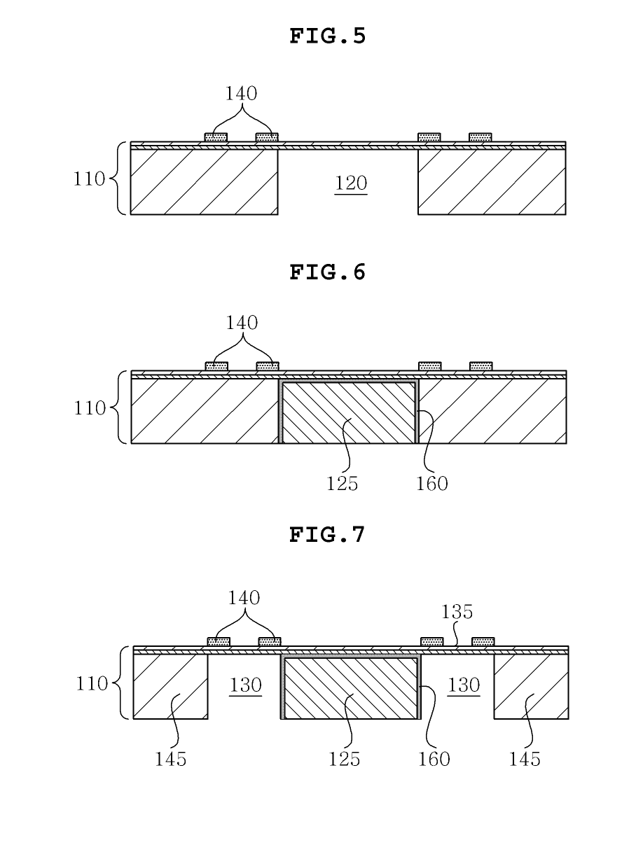

Next, as shown in FIG. 5, the depressed first concave part 120 is formed in the other surface of the base substrate 110. Here, the first concave part 120 may be formed by disposing a mask and then performing selective etching.

Thereafter, as shown in FIG. 6, the mass body 125 is formed in the first concave part 120 by filling the filling material including the metal therein. Here, the filling material may be a metal or a combination of a metal and a polymer (or a polymer matrix composite). A process of forming the mass body 125 in the first concave part 120 by filling the filling material therein will be described in detail. An interface layer 160 may be first formed in the first concave part 120 in order to improve wettability before the filling material is filled. Here, the interface layer 160 may be formed of a gold plating layer, or the like. Then, the filling material in which the metal is melted is filled in the first concave part 120 and then solidified, thereby forming the mass body 125. At this time, in order to prevent the piezoelectric element 140 from being damaged due to a temperature at which the metal is melted, a melting point of the metal needs to be lower than the Curie temperature of the piezoelectric element 140.

Then, as shown in FIG. 7, the depressed second concave part 135 is formed in the other surface of the base substrate 110 at the outer side of the mass body 125 and the flexible part 135 is formed on the upper portion of the second concave part 135 in the base substrate 110. Here, the second concave part 130 may be formed by disposing a mask and then performing selective etching. As described above, when the second concave part 130 is formed at the outer side of the mass body 125, since a thickness of a part in which the second concave part 130 is formed in the base substrate 110 becomes thin, the part may be used as the flexible part 135. In addition, an edge of the base substrate 110 remaining at an outer side of the second concave part 130 may be used as the post 145.

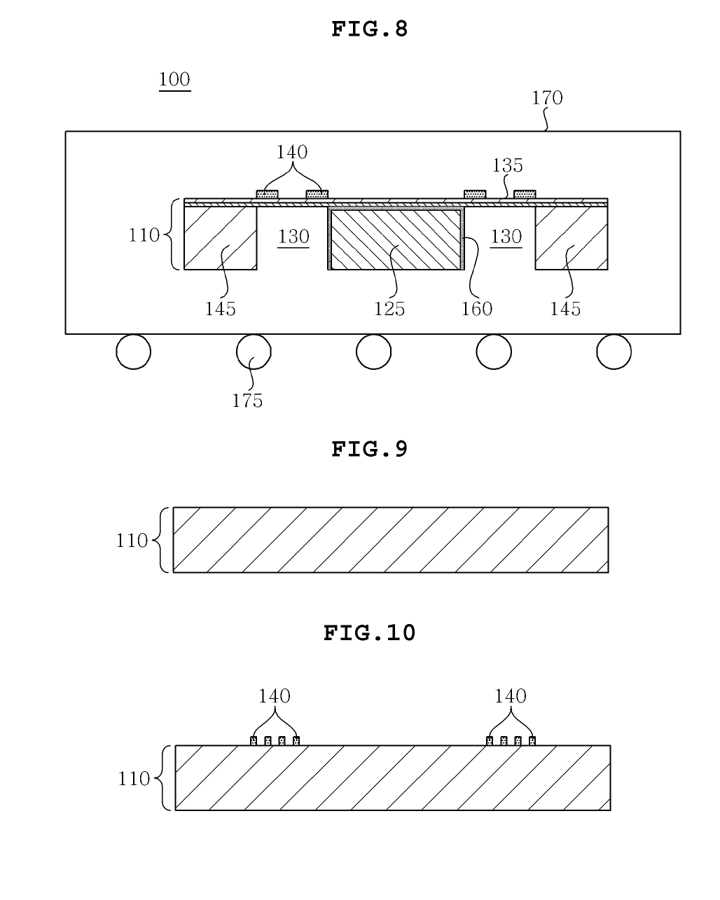

Next, as shown in FIG. 8, the base substrate 110 is enclosed with the package 170 and the connection parts 175 for an SMT formed using the solder are formed on the package 170. Here, the package 170, which protects the base substrate 110 from external impact, may be formed by performing a molding process in a mold machine and then performing a post mold cure (PMC) process in an oven. In addition, the connection parts 175 for an SMT are formed using the solder on the package 170. When the connection part 175 for an SMT is formed using the solder, the solder forming the connection part 175 for an SMT needs to have a melting point lower than that of a metal forming the mass body 125 in order to prevent the mass body 125 from being melted at a temperature at which the solder is melted (that is, the metal forming the mass body 125 needs to have a melting point higher than that of the solder forming the connection part 175 for an SMT). For example, when a solder in which a ratio of tin (Sn) to lead (pb) is approximately 63%:37% is used as the solder forming the connection part 175 for an SMT, a melting point of the solder forming the connection part 175 for an SMT becomes a eutectic temperature (approximately 183□) and the metal forming the mass body 125 needs to have a melting temperature higher than the eutectic temperature. Particularly, when a solder is used as the metal forming the mass body 125, a ratio of tin (Sn) to lead (Pb) is controlled to allow the solder to have a melting point higher than the eutectic temperature, thereby making it possible to prevent the mass body 125 from being melted when the connection part 175 for an SMT is formed.

FIGS. 9 to 14 are cross-sectional views sequentially showing a method of manufacturing an inertial sensor according to the second preferred embodiment of the present invention.

As shown in FIGS. 9 to 14, the method of manufacturing an inertial sensor 200 according to the present embodiment includes (A) forming piezoelectric elements 140 on one surface of a base substrate 110, (B) forming a penetration part 150 penetrating through the base substrate 110, (C) forming a mass body 125 in the penetration part 150 by filling a filling material including a metal therein, (D) forming a flexible part 135 patterned so as to penetrate through the base substrate 110 at an outer side of the mass body 125, and (E) enclosing the base substrate 110 with a package 170 and forming connection parts 175 for an SMT on the package 170, the connection parts 175 for an SMT being formed using a solder, wherein the metal has a melting point lower than the Curie temperature of the piezoelectric elements 140 and higher than that of the solder forming the connection parts 175 for an SMT.

First, as shown in FIG. 9, the base substrate 110 is prepared. Here, as the base substrate 110, a silicon substrate on which a MEMS process is easily performed may be used. However, the base substrate 110 is not necessarily limited to being the silicon substrate but may be all substrates known in the art.

Then, as shown in FIG. 10, the piezoelectric elements 140 are formed on one surface of the base substrate 110. Here, the piezoelectric element 140 may be formed by depositing lead zirconate titanate (PZT), barium titanate (BaTiO₃), lead titanate (PbTiO₃), lithium niobate (LiNbO₃), quartz (SiO₂), or the like. In addition, a wiring layer (not shown) connected to the piezoelectric elements 140 to may be formed in order to drive the mass body 125 or sense the displacement of the mass body 125 through the piezoelectric elements 140.

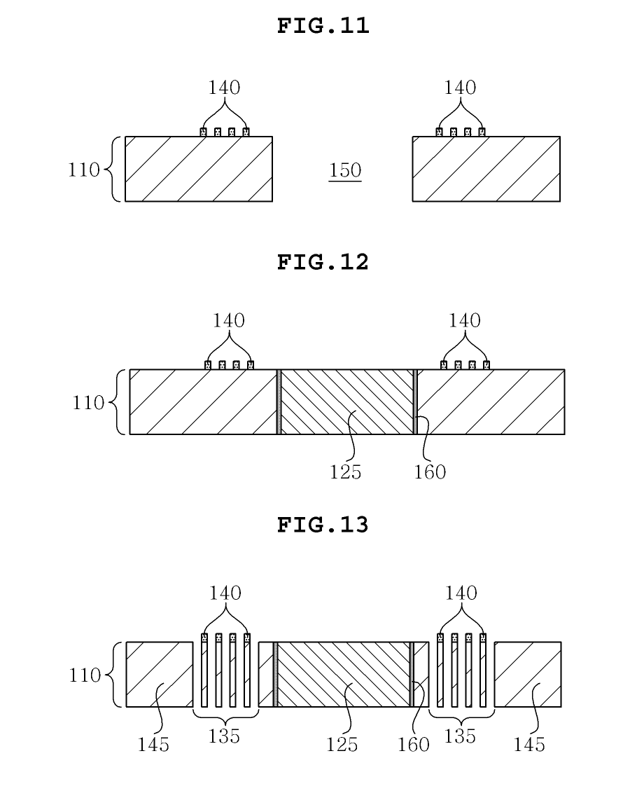

Then, as shown in FIG. 11, the penetration part 150 penetrating through the base substrate 110 is formed. Here, the penetration part 150 may be formed by disposing a mask and then performing selective etching.

Thereafter, as shown in FIG. 12, the mass body 125 is formed in the penetration part 150 by filling the filling material including the metal therein. Here, the filling material may be a metal or a combination of a metal and a polymer (or a polymer matrix composite). A process of forming the mass body 125 in the penetration part 150 by filling the filling material therein will be described in detail. An interface layer 160 such as a gold plating layer, or the like, may be first formed in the penetration part 150 in order to improve wettability before the filling material is filled. Then, the metal is melted to be filled in the penetration part 150 and then solidified, thereby forming the mass body 125. At this time, in order to prevent the piezoelectric element 140 from being damaged due to a temperature at which the metal is melted, a melting point of the metal needs to be lower than the Curie temperature of the piezoelectric element 140.

Then, as shown in FIG. 13, the flexible part 135 patterned so as to penetrate through the base substrate 110 at the outer side of the mass body 125 is formed. Here, the flexible part 135 may be formed by disposing a mask and then performing selective etching. As described above, when the patterning is performed so as to penetrate through the base substrate 110 at the outer side of the mass body 125, the flexible part 135 having a cantilever shape may be formed. In addition, an edge of the base substrate 110 remaining at an outer side of the flexible part 135 may be used as the post 145.

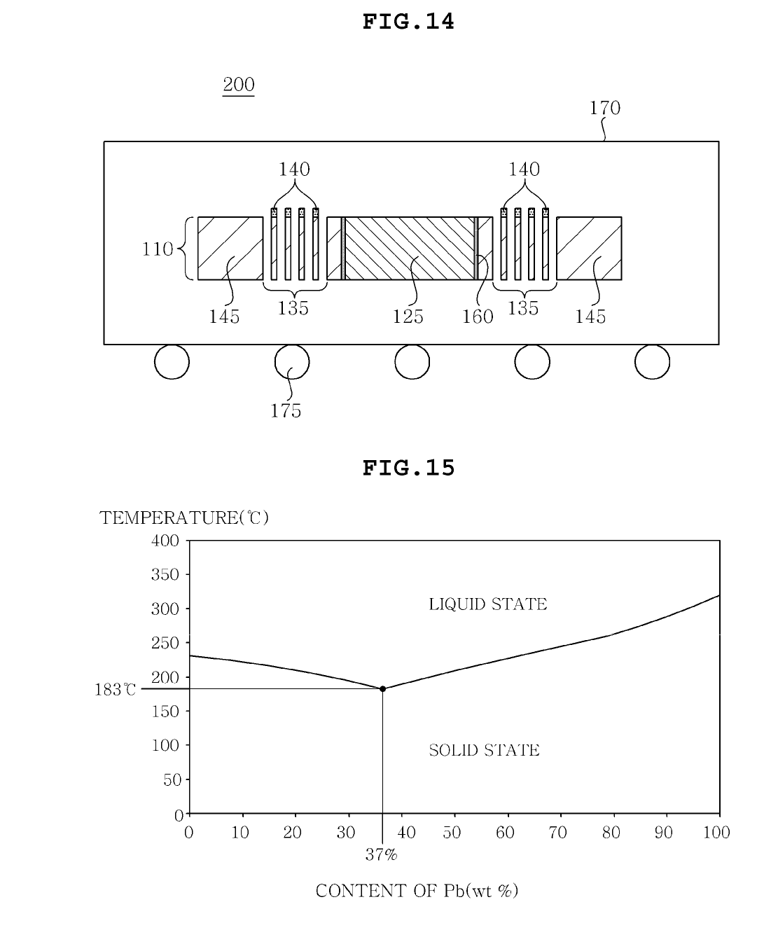

Next, as shown in FIG. 14, the base substrate 110 is enclosed with the package 170 and the connection parts 175 for an SMT formed using the solder are formed on the package 170. When the connection part 175 for an SMT is formed using the solder, the solder forming the connection part 175 for an SMT needs to have a melting point lower than that of a metal forming the mass body 125 to in order to prevent the mass body 125 from being melted at a temperature at which the solder is melted. As a result, the metal forming the mass body 125 needs to have a melting point higher than that of the solder forming the connection part 175 for an SMT.

Similar to the first preferred embodiment described above, even in the present embodiment, when a solder in which a ratio of tin (Sn) to lead (pb) is approximately 63%:37% is used as the solder forming the connection part 175 for an SMT, a melting point of the solder forming the connection part 175 for an SMT becomes a eutectic temperature (approximately 183° C.) and the metal forming the mass body 125 needs to have a melting temperature higher than the eutectic temperature. Particularly, when a solder is used as the metal forming the mass body 125, a ratio of tin (Sn) to lead (Pb) is controlled to allow the solder to have a melting point higher than the eutectic temperature, thereby making it possible to prevent the mass body 125 from being melted when the connection part 175 for an SMT is formed.

Meanwhile, in the method of manufacturing an inertial sensor 100 or 200 according to the preferred embodiment of the present invention, the base substrate 110 (the SOI substrate, or the like) that may be precisely processed is etched and the mass body 125 is then formed using the etched base substrate as a mold. Therefore, even though the mass body 125 is formed by filling the filling material including the metal, a processing error is not generated and precision is not deteriorated.

As set forth, according to the preferred embodiments of the present invention, the mass body is formed of the metal having relatively high density, thereby making it possible to improve sensitivity of the inertial sensor, and Brownian noise is decreased, thereby making it possible to increase a signal to noise ratio.

In addition, according to the preferred embodiments of the present invention, the metal forming the mass body has a melting point lower than the Curie temperature of the piezoelectric element, thereby making it possible to prevent the piezoelectric element from being damaged when the mass body is formed. Further, according to the preferred embodiments of the present invention, the metal forming the mass body has a melting point higher than that of the solder forming the connection part for an SMT, thereby making it possible to prevent the mass body from being melted when the connection part for an SMT is formed.

Although the preferred embodiments of the present invention have been disclosed for illustrative purposes, they are for specifically explaining the present invention and thus an inertial sensor and a method of manufacturing the same according to the present invention are not limited thereto, but those skilled in the art will appreciate that various modifications, additions and substitutions are possible, without departing from the scope and spirit of the invention as disclosed in the accompanying claims. Accordingly, any and all modifications, variations or equivalent arrangements should be considered to be within the scope of the invention, and the detailed scope of the invention will be disclosed by the accompanying claims.

What is claimed is:

1. An inertial sensor comprising:
a flexible part;
a mass body movably supported by the flexible part and including a metal;
a post supporting the flexible part;
piezoelectric elements driving the mass body or sensing displacement of the mass body; and
a package enclosing the flexible part, the mass body, and the post,
wherein the metal has a melting point lower than the Curie temperature of the piezoelectric to elements and higher than that of a solder forming connection parts for a surface mounting technology (SMT) provided on the package.

2. The inertial sensor as set forth in claim 1, wherein the piezoelectric element is formed of lead zirconate titanate (PZT), barium titanate (BaTiO₃), lead titanate (PbTiO₃), lithium niobate (LiNbO₃), or quartz (SiO₂).

3. The inertial sensor as set forth in claim 1, wherein the solder forming the connection part for an SMT has a ratio of tin (Sn) to lead (Pb) of 63%:37%.

4. The inertial sensor as set forth in claim 1, wherein the metal is a solder having a melting point higher than that of the solder forming the connection part for an SMT.

5. The inertial sensor as set forth in claim 1, wherein the metal is a solder formed of tin (Sn) and lead (Pb), and the solder has a melting point higher than a eutectic temperature of tin (Sn) and lead (Pb).

6. The inertial sensor as set forth in claim 1, wherein the mass body includes an interface layer formed therein.

7. An inertial sensor comprising:
a flexible part;
a mass body movably supported by the flexible part and including a metal;
a post supporting the flexible part;
piezoelectric elements driving the mass body or sensing displacement of the mass body; and
connection parts for an SMT provided on the package enclosing the flexible part, the mass body, and the post and formed using a solder,
wherein the metal has a melting point lower than the Curie temperature of the piezoelectric elements and higher than that of the solder forming the connection parts for an SMT.

8. The inertial sensor as set forth in claim 7, further comprising a main board electrically connected to the connection parts for an SMT.

9. A method of manufacturing an inertial sensor, the method comprising:
(A) forming piezoelectric elements on one surface of a base substrate;
(B) forming a first concave part in the other surface of the base substrate;
(C) forming a mass body in the first concave part by filling a filling material including a metal therein;
(D) forming a depressed second concave part in the other surface of the base substrate at an outer side of the mass body and forming a flexible part on an upper portion of the second concave part in the base substrate; and
(E) enclosing the base substrate with a package and forming connection parts for an SMT on the package, the connection parts for an SMT being formed using a solder,
wherein the metal has a melting point lower than the Curie temperature of the piezoelectric elements and higher than that of the solder forming the connection parts for an SMT.

10. The method as set forth in claim 9, wherein the piezoelectric element is formed of lead zirconate titanate (PZT), barium titanate (BaTiO₃), lead titanate (PbTiO₃), lithium niobate (LiNbO₃), or quartz (SiO₂).

11. The method as set forth in claim 9, wherein the solder forming the connection part for an SMT has a ratio of tin (Sn) to lead (Pb) of 63%:37%.

12. The method as set forth in claim 9, wherein the metal is a solder having a melting point higher than that of the solder forming the connection part for an SMT.

13. The method as set forth in claim 9, wherein the metal is a solder formed of tin (Sn) and lead (Pb), and the solder has a melting point higher than a eutectic temperature of tin (Sn) and lead (Pb).

14. The method as set forth in claim 9, further comprising, before step (C), forming an interface layer in the first concave part.

15. A method of manufacturing an inertial sensor, the method comprising:
(A) forming piezoelectric elements on one surface of a base substrate;
(B) forming a penetration part penetrating through the base substrate;
(C) forming a mass body in the penetration part by filling a filling material including a metal therein;
(D) forming a flexible part patterned so as to penetrate through the base substrate at an outer side of the mass body; and
(E) enclosing the base substrate with a package and forming connection parts for an SMT on the package, the connection parts for an SMT being formed using a solder,
wherein the metal has a melting point lower than the Curie temperature of the piezoelectric elements and higher than that of the solder forming the connection parts for an SMT.

16. The method as set forth in claim 15, wherein the piezoelectric element is formed of lead zirconate titanate (PZT), barium titanate (BaTiO₃), lead titanate (PbTiO₃), lithium niobate (LiNbO₃), or quartz (SiO₂).

17. The method as set forth in claim 15, wherein the solder forming the connection part for an SMT has a ratio of tin (Sn) to lead (Pb) of 63%:37%.

18. The method as set forth in claim 15, wherein the metal is a solder having a melting point higher than that of the solder forming the connection part for an SMT.

19. The method as set forth in claim 15, wherein the metal is a solder formed of tin (Sn) and lead (Pb), and the solder has a melting point higher than a eutectic temperature of tin (Sn) and lead (Pb).

20. The method as set forth in claim 15, further comprising, before step (C), forming an interface layer in the penetration part.
